(19) United States
(12) Patent Application Publication
(10) Pub. No.: US 2026/0247617 A1
(43) Pub. Date: Aug. 20, 2026

(54) MEMORY DEVICE

(71) Applicant: Kioxia Corporation, Tokyo (JP)

(72) Inventors: Naoki TSUBOI, Yokohama Kanagawa (JP); Takeshi SHIMANE, Matsuda Chiba (JP); Takashi IZUMIDA, Kamakura Kanagawa (JP)

(73) Assignee: Kioxia Corporation, Tokyo (JP)

(21) Appl. No.: 19/238,696

(22) Filed: Jun. 16, 2025

(30) Foreign Application Priority Data
Feb. 19, 2025 (JP) 2025-025218

(51) Int. Cl. H10B 43/27; H01L 23/00; H01L 25/065; H01L 25/18; H10B 43/10; H10B 43/35; H10B 43/40; H10B 80/00

(52) U.S. Cl. CPC H10B 43/27; H10B 43/10; H10B 43/35; H10B 43/40; H10B 80/00; H10W 90/00; H10W 90/792

(57) ABSTRACT

According to one embodiment, a memory device includes: a first region, a third region, and a second region provided in a substrate, arranged away from each other in a first direction in this order, and each including a first conductive impurity; a fourth region provided in the third region, and including a second conductive impurity different from the first conductive impurity; a first conductive layer provided above the first region, and including a first opening; a second conductive layer provided above the second region, and including a second opening; a first contact connected to the first region, and passing through the first opening; a second contact connected to the second region, and passing through the second opening; a first memory cell connected to the first contact; and a second memory cell connected to the second contact.

### CROSS-REFERENCE TO RELATED APPLICATIONS

This application is based upon and claims the benefit of priority from Japanese Patent Application No. 2025-025218, filed Feb. 19, 2025, the entire contents of which are incorporated herein by reference.

### FIELD

Embodiments described herein relate generally to a memory device.

### BACKGROUND

As memory devices capable of storing data in a non-volatile manner, NAND flash memories have been known. In memory devices, such as NAND flash memories, a three-dimensional memory structure is employed for high integration and large capacity.

### BRIEF DESCRIPTION OF DRAWINGS

FIG. 1 is a block diagram illustrating an exemplary configuration of a memory system including a memory device according to an embodiment.

FIG. 2 is a circuit diagram illustrating an exemplary circuit configuration of a memory cell array included in the memory device according to the embodiment.

FIG. 3 is a plan view illustrating an exemplary planar layout of the memory cell array included in the memory device according to the embodiment.

FIG. 4 is a plan view illustrating an example of a region IV of FIG. 3 in the planar layout of the memory cell array included in the memory device according to the embodiment.

FIG. 5 is a sectional view taken along line V-V of FIG. 4, illustrating an exemplary sectional structure of the memory cell array included in the memory device according to the embodiment.

FIG. 6 is a sectional view taken along line VI-VI of FIG. 5, illustrating an exemplary sectional structure of a memory pillar included in the memory cell array according to the embodiment.

FIG. 7 is a circuit diagram illustrating an exemplary circuit configuration of a row decoder module included in the memory device according to the embodiment.

FIG. 8 is a plan view illustrating an exemplary planar layout of the row decoder module included in the memory device according to the embodiment.

FIG. 9 is a plan view illustrating an example of a region IX of FIG. 8 in the planar layout of the row decoder module included in the memory device according to the embodiment.

FIG. 10 is a sectional view taken along line X-X of FIG. 9, illustrating an exemplary sectional structure of the row decoder module included in the memory device according to the embodiment.

FIG. 11 is a schematic perspective view illustrating a bonding structure for the memory device according to the embodiment.

FIG. 12 is a sectional view illustrating an exemplary sectional structure of the memory device according to the embodiment.

FIG. 13 illustrates an exemplary potential distribution on a transistor included in a memory device according to a comparative example.

FIG. 14 illustrates an exemplary potential distribution on a transistor included in the memory device according to the embodiment.

FIG. 15 illustrates an exemplary characteristic of a transistor included in the memory device according to the embodiment.

FIG. 16 is a plan view illustrating an exemplary planar layout of a row decoder module included in a memory device according to a first modification.

FIG. 17 is a plan view illustrating an exemplary planar layout of a row decoder module included in a memory device according to a second modification.

### DETAILED DESCRIPTION

In general, according to one embodiment, a memory device includes a first region, a third region, and a second region provided in a substrate, arranged away from each other in a first direction in this order, and each including a first conductive impurity; a fourth region provided in the third region, and including a second conductive impurity different from the first conductive impurity; a first conductive layer provided above the first region, and including a first opening; a second conductive layer provided above the second region, and including a second opening; a first contact connected to the first region, and passing through the first opening; a second contact connected to the second region, and passing through the second opening; a first memory cell connected to the first contact; and a second memory cell connected to the second contact.

Embodiments will be described below with reference to the drawings. The dimensions and ratio of each drawing are not necessarily identical to realities.

Note that, in the following description, constituent elements substantially the same in function and configuration are denoted with the same reference signs. In particular, for distinction between constituent elements similar in configuration, the same reference signs may have their ends denoted with mutually different letters or numbers.

### 1. CONFIGURATION

### 1.1 Memory System

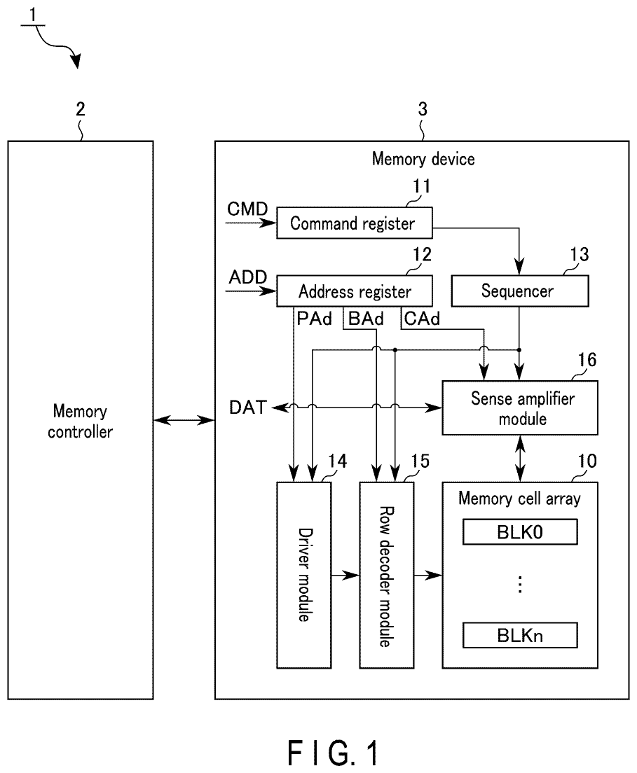

FIG. 1 is a block diagram illustrating an exemplary configuration of a memory system including a memory device according to an embodiment. A memory system 1 is configured to be connected to an external host (not illustrated). Examples of the memory system 1 include memory cards, such as SD™ cards, universal flash storage (UFS), and solid state drives (SSD). The memory system 1 includes a memory controller 2 and a memory device 3.

The memory controller 2 is formed with an integrated circuit, such as a system on a chip (SoC). The memory controller 2 controls the memory device 3, based on a request from the host. Specifically, for example, the memory controller 2 writes, to the memory device 3, data required to be written by the host. The memory controller 2 reads, from the memory device 3, data required to be read by the host and then transmits the data to the host.

The memory device 3 corresponds to a non-volatile memory. The memory device 3 is, for example, a NAND flash memory. The memory device 3 stores data in a non-volatile manner.

Communication between the memory controller 2 and the memory device 3 is based on, for example, a single data rate (SDR) interface, a toggle double data rate (DDR) interface, or an open NAND flash interface (ONFI).

### 1.2 Memory Device

Next, the internal configuration of the memory device according to the embodiment will be described with reference to the block diagram illustrated in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The number of blocks BLK included in the memory cell array 10 may be one. The blocks BLK are each an aggregate of memory cells. The blocks BLK are each used, for example, as the unit of data erasure. The memory cell array 10 is provided with a plurality of bit lines and a plurality of word lines. For example, each memory cell is associated with one bit line and one word line. The configuration of the memory cell array 10 will be described in detail later.

The command register 11 stores a command CMD received by the memory device 3 from the memory controller 2. The command CMD includes an order for the sequencer 13 to perform, for example, a read operation, a write operation, or an erase operation.

The address register 12 stores address information ADD received by the memory device 3 from the memory controller 2. The address information ADD includes, for example, block address BAd, page address PAd, and column address CAd. For example, the block address BAd, the page address PAd, and the column address CAd are used for selecting a block BLK, a word line, and a bit line, respectively.

The sequencer 13 controls the operation of the entire memory device 3. For example, based on the command CMD stored in the command register 11, the sequencer 13 controls the driver module 14, the row decoder module 15, and the sense amplifier module 16 to perform the read operation, the write operation, or the erase operation.

The driver module 14 generates a voltage to be used for the read operation, the write operation, or the erase operation. Then, for example, based on the page address PAd stored in the address register 12, the driver module 14 applies the generated voltage to a signal line corresponding to the selected word line.

Based on the block address BAd stored in the address register 12, the row decoder module 15 selects the corresponding one block BLK in the memory cell array 10. Then, for example, the row decoder module 15 transfers the voltage applied to the signal line corresponding to the selected word line to the selected word line in the selected block BLK.

In the write operation, the sense amplifier module 16 applies a desired voltage to each bit line in accordance with write data DAT received from the memory controller 2. In the read operation, the sense amplifier module 16 determines data stored in a memory cell based on the voltage of the bit line and then transfers a determination result as read data DAT to the memory controller 2.

### 1.3 Memory Cell Array

Next, the configuration of the memory cell array included in the memory device according to the embodiment will be described.

### 1.3.1 Circuit Configuration

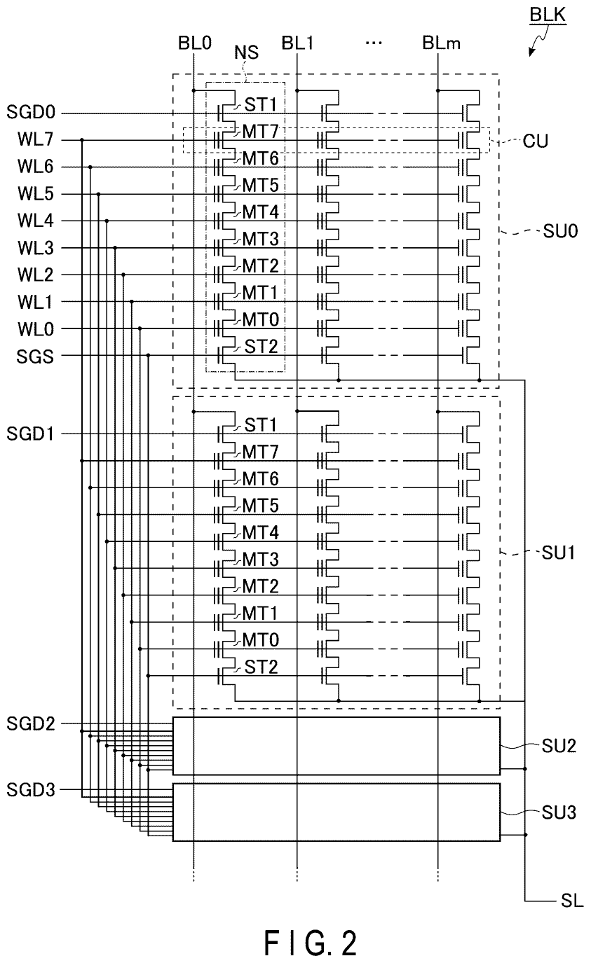

FIG. 2 is a circuit diagram illustrating an exemplary circuit configuration of the memory cell array included in the memory device according to the embodiment. Referring to FIG. 2, one block BLK is illustrated from the blocks BLK included in the memory cell array 10. As illustrated in FIG. 2, the block BLK includes, for example, four string units SU0 to SU3.

Each string unit SU includes a plurality of NAND strings NS associated one-to-one to bit lines BL0 to BLm (m is an integer of 1 or more). The number of bit lines BL may be one. Each NAND string NS includes, for example, memory cell transistors MT0 to MT7 and select transistors ST1 and ST2. Each memory cell transistor MT includes a control gate and a charge storage film and stores data in a non-volatile manner. The select transistors ST1 and ST2 are each used to select the corresponding string unit SU at the time of each type of operation.

In each NAND string NS, the memory cell transistors MT0 to MT7 are connected in series. The drain of the select transistor ST1 is connected to the associated bit line BL. The source of the select transistor ST1 is connected to one end of the memory cell transistors MT0 to MT7 connected in series. The drain of the select transistor ST2 is connected to the other end of the memory cell transistors MT0 to MT7 connected in series. The source of the select transistor ST2 is connected to a source line SL.

The control gates of the memory cell transistors MT0 to MT7 of each NAND string NS in the same block BLK are connected to word lines WL0 to WL7, respectively. The gates of the select transistors ST1 in the string unit SU0 are connected to a select gate line SGD0. The gates of the select transistors ST1 in the string unit SU1 are connected to a select gate line SGD1. The gates of the select transistors ST1 in the string unit SU2 are connected to a select gate line SGD2. The gates of the select transistors ST1 in the string unit SU3 are connected to a select gate line SGD3. The gates of the select transistors ST2 are connected to a select gate line SGS.

Mutually different column addresses are allocated to the bit lines BL0 to BLm. Each bit line BL is shared by the NAND strings NS to which the same column address is allocated between the blocks BLK. The word lines WL0 to WL7 are each provided for each block BLK. The source line SL is shared, for example, between the blocks BLK.

An aggregate of memory cell transistors MT connected in common to one word line WL of the word lines WL in one string unit SU is referred to as a cell unit CU, for example. For example, the storage capacity of a cell unit CU, in which the memory cell transistors MT each store 1-bit data, is defined as “1-page data”. Such a cell unit CU may have a storage capacity corresponding to two-page data or data exceeding the two page data, depending on the number of bits of data that the memory cell transistors MT store.

Note that the circuit configuration of the memory cell array 10 included in the memory device 3 is not limited to the above-described configuration. For example, the number of string units SU included in each block BLK may be designed to be any number. The number of memory cell transistors MT, the number of select transistors ST1, and the number of select transistors ST2 included in each NAND string NS may be each designed to be any number.

### 1.3.2 Planar Layout

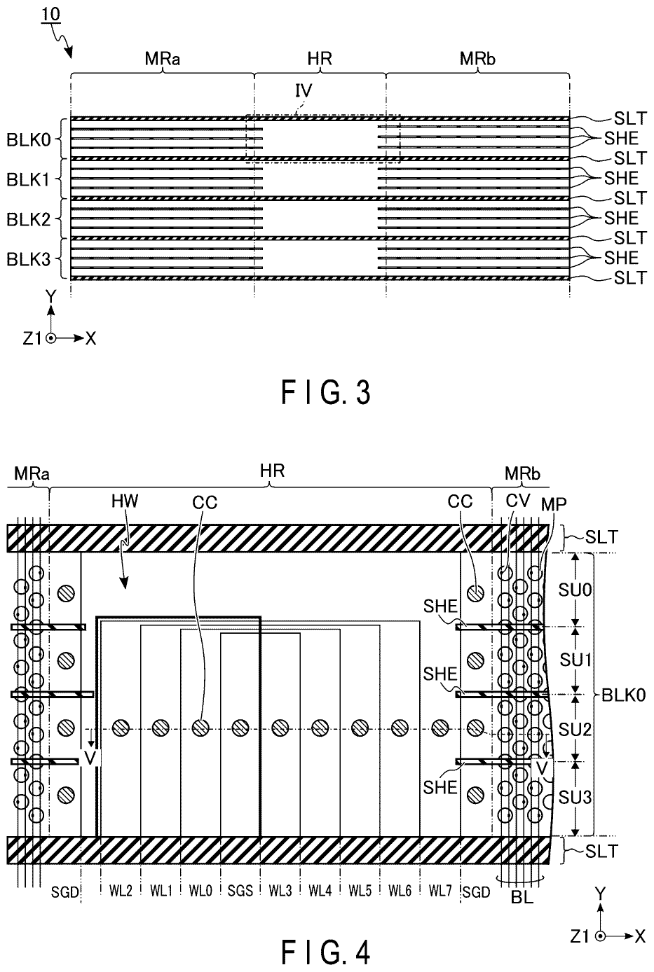

FIG. 3 is a plan view illustrating an exemplary planar layout of the memory cell array included in the memory device according to the embodiment. Referring to FIG. 3, four blocks BLK0 to BLK3 are exemplified from the blocks BLK included in the memory cell array 10.

The memory cell array 10 has a stacked interconnect structure. The stacked interconnect structure corresponds to a structure in which interconnect layers (word lines WL0 to WL7 and select gate lines SGD and SGS) are stacked.

Hereinafter, a plane almost parallel to the stacked face of the interconnect layers is defined as an XY plane. On the XY plane, mutually orthogonal directions are defined as an X direction and a Y direction. A direction from the select gate line SGS to the select gate line SGD, which is almost orthogonal to the XY plane, is defined as a Z1 direction. A direction from the select gate line SGD to the select gate line SGS, which is almost orthogonal to the XY plane, is defined as a Z2 direction. Provided that no distinction between the Z1 direction and the Z2 direction is required, the Z1 direction and the Z2 direction are referred to as a Z direction.

As illustrated in FIG. 3, the stacked interconnect structure includes memory regions MRa and MRb and a hookup region HR arranged in the X direction. The memory regions MRa and MRb correspond to regions in which the memory cell transistors MT are provided. The hookup region HR corresponds to a region in which a contact, through which each interconnect layer and the row decoder module 15 are electrically connected, is provided. The hookup region HR is located, for example, between the memory region MRa and the memory region MRb.

The blocks BLK each include a portion extending in the X direction across the memory region MRa, the hookup region HR, and the memory region MRb in the stacked interconnect structure. The blocks BLK are arranged in the Y direction. The memory cell array 10 includes, for example, a plurality of members SLT and a plurality of members SHE.

Each member SLT extends in the X direction across the memory region MRa, the hookup region HR, and the memory region MRb. The members SLT are arranged in the Y direction. Each member SLT has, for example, a structure in which an insulator is embedded. Each member SLT partitions the interconnect layers adjacent through the member SLT. In the memory cell array 10, each of the regions segmented by the members SLT corresponds to one block BLK.

The members SHE include a plurality of members SHE arranged in the Y direction in the memory region MRa and a plurality of members SHE arranged in the Y direction in the memory region MRb. Each member SHE located in the memory region MRa extends in the X direction across the memory region MRa. Each member SHE located in the memory region MRb extends in the X direction across the memory region MRb. In the example of FIG. 3, in each of the memory regions MRa and MRb, three members SHE are disposed between two members SLT adjacent in the Y direction. Each member SHE has, for example, a structure in which an insulator is embedded. Each member SHE partitions the select gate lines SGD in the interconnect layers adjacent through the member SHE. In the memory cell array 10, a region segmented by a pair of adjacent members SLT and SHE or a region segmented by a pair of two adjacent members SHE corresponds to one string unit SU.

Note that the planar layout of the memory cell array 10 may be another layout. For example, the number of members SHE disposed between two adjacent members SLT may be designed to be any number. The number of string units SU included in each block BLK may be changed based on the number of members SHE disposed between two adjacent members SLT.

FIG. 4 is a plan view illustrating an example of a region IV of FIG. 3 in the planar layout of the memory cell array included in the memory device according to the embodiment. Referring to FIG. 4, the hookup region HR and the boundary between the hookup region HR and each of the memory regions MRa and MRb in the block BLK0 are illustrated.

First, the planar layout in each of the memory regions MRa and MRb of the memory cell array 10 will be described.

As illustrated in FIG. 4, the block BLK0 of the memory cell array 10 includes a plurality of memory pillars MP, a plurality of contacts CV, and a plurality of bit lines BL in each of the memory regions MRa and MRb.

Each memory pillar MP functions as one NAND string NS. The memory pillars MP are arranged in 19 rows in a staggered manner, for example, in the region between two adjacent members SLT. For example, the memory pillars MP in the fifth row, the memory pillars MP in the tenth row, and the memory pillars MP in the fifteenth row from the upper side of the drawing each have one member SHE overlapping therewith.

The bit lines BL are arranged in the X direction. Each bit line BL overlaps at least one memory pillar MP in each string unit SU. In the example of FIG. 4, each memory pillar MP has two bit lines BL overlapping therewith. The memory pillars MP are each electrically connected, through a contact CV, to one bit line BL of the overlapping bit lines BL. Meanwhile, a contact CV may be omitted between each memory pillar MP in contact with two different select gate lines SGD (namely, each memory pillar MP overlapping a member SHE) and a bit line BL.

Note that the planar layout in each memory region MR may be another layout. For example, the number of memory pillars MP and the number of members SHE disposed between two adjacent members SLT and the arrangement may be changed as appropriate. The number of bit lines BL overlapping each memory pillar MP may be designed to be any number.

Next, the planar layout in the hookup region HR of the memory cell array 10 will be described.

The memory cell array 10 includes a plurality of contacts CC in the hookup region HR. The stacked interconnect structure includes a terrace portion and a highway portion HW in the hookup region HR. The terrace portion corresponds to a portion that an interconnect layer has without overlapping any upper interconnect layer in the Z1 direction in the stacked interconnect structure. The highway portion HW corresponds to a portion located side by side in the Y direction with respect to the terrace portion.

The stacked interconnect structure includes a staircase structure at the terrace portion. In the example of FIG. 4, steps are formed one-to-one between the select gate line SGS and the word line WL0, between the word line WL0 and the word line WL1,..., between the word line WL6 and the word line WL7, and between the word line WL7 and the select gate line SGD. Note that all the steps are not necessarily arranged in one direction. For example, some of the select gate line SGS and the word lines WL0 to WL7 (in the example of FIG. 4, the select gate line SGS and the word lines WL0 to WL2) may form descending steps in the X direction, and the others (in the example of FIG. 4, the word lines WL3 to WL7) may form ascending steps in the X direction. For example, some of the select gate line SGS and the word lines WL0 to WL7 may form steps in the Y direction.

The interconnect layers in the memory region MRa and the interconnect layers in the memory region MRb except the select gate line SGD are provided continuously through the highway portion HW. That is, the highway portion HW corresponds to a portion that electrically connects the interconnect layers in the memory region MRa and the interconnect layers in the memory region MRb except the select gate line SGD. The select gate line SGD is interrupted by the hookup region HR between the memory region MRa and the memory region MRb.

The contacts CC are each a conductor used for connection between the row decoder module 15 and one of the interconnect layers. A plurality of contacts CC corresponding to each block BLK is connected one-to-one to the respective terrace portions of the select gate lines SGS and SGD and the word lines WL0 to WL7 in the hookup region HR. Note that the select gate line SGD on the side of location of the memory region MRa and the select gate line SGD on the side of location of the memory region MRb are provided with mutually different contacts CC. The select gate line SGD on the side of location of the memory region MRa and the select gate line SGD on the side of location of the memory region MRb, which correspond to the same string unit SU, are electrically connected, for example, through the respective contacts CC and an upper interconnect layer not illustrated.

### 1.3.3 Sectional Structure

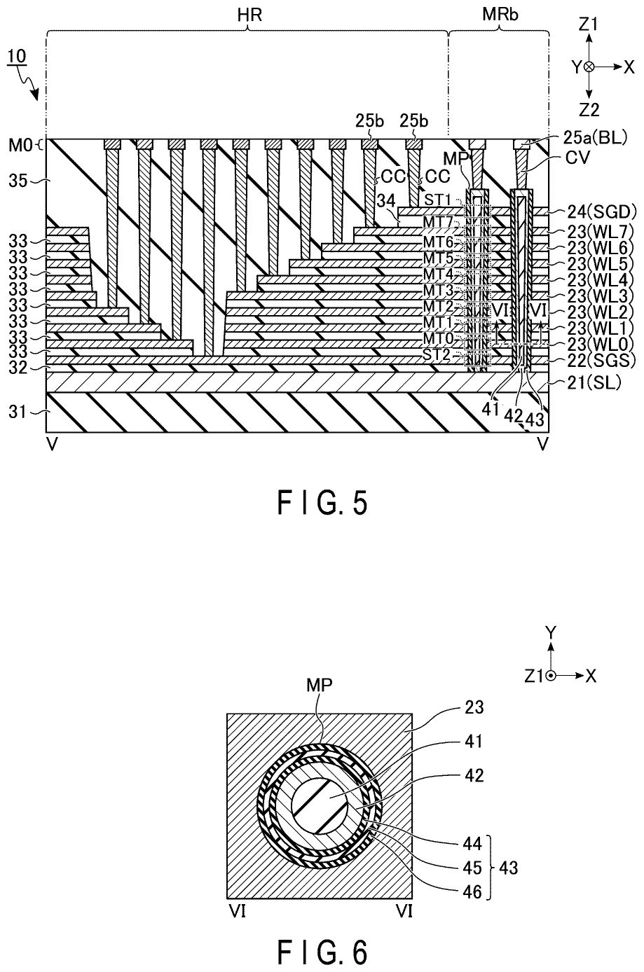

FIG. 5 is a sectional view taken along line V-V of FIG. 4, illustrating an exemplary sectional structure of the memory cell array included in the memory device according to the embodiment. Referring to FIG. 5, a sectional structure of part of the memory region MRb and the hookup region HR is illustrated.

As illustrated in FIG. 5, the memory cell array 10 includes, for example, a semiconductor layer 21, interconnect layers 22, 23, and 24, conductive layers 25 (25a and 25b), and insulating layers 31, 32, 33, 34, and 35. The insulating layers 31 to 35 each include, for example, silicon dioxide. Referring to FIG. 5, the Z1 direction corresponds to the up direction of the drawing.

The semiconductor layer 21 is provided on the insulating layer 31. For example, the semiconductor layer 21 is formed like a plate and expands along the XY plane. The semiconductor layer 21 includes, for example, silicon and is used as the source line SL.

The insulating layer 32 is provided on the semiconductor layer 21. The interconnect layer 22 is provided on the insulating layer 32. For example, the interconnect layer 22 is formed like a plate and expands along the XY plane. The interconnect layer 22 includes, for example, tungsten and is used as the select gate line SGS.

The insulating layers 33 and the interconnect layers 23 are alternately provided on the interconnect layer 22. For example, the interconnect layers 23 are each formed like a plate and expand along the XY plane. The interconnect layers 23 each include, for example, tungsten and are used as the word lines WL0 to WL7 in order from the side of location of the semiconductor layer 21.

The insulating layer 34 is provided on the uppermost interconnect layer 23. The interconnect layer 24 is provided on the insulating layer 34. For example, the interconnect layer 24 is formed like a plate and expands along the XY plane. The interconnect layer 24 includes, for example, tungsten and is used as the select gate line SGD.

In the memory region MRb, the memory pillars MP each extend in the Z direction and penetrate through the interconnect layers 22 to 24 and the insulating layers 32 to 34. For example, the memory pillars MP taper such that their diameters decrease in the Z2 direction. Note that, although are not illustrated in FIG. 5, the memory pillars MP in the memory region MRa are similarly provided.

The memory pillars MP each include, for example, a core film 41, a semiconductor film 42, and a stacked film 43. The core film 41 is an insulator extending in the Z direction. The core film 41 is covered with the semiconductor film 42. The semiconductor film 42 has a lower portion in contact with the semiconductor layer 21. The semiconductor film 42 is laterally covered with the stacked film 43.

FIG. 6 is a sectional view taken along line VI-VI of FIG. 5, illustrating an exemplary sectional structure of a memory pillar included in the memory device according to the embodiment. Referring to FIG. 6, a cross section, which includes a memory pillar MP and an interconnect layer 23 and is parallel to the XY plane, is illustrated. As illustrated in FIG. 6, the stacked film 43 includes, for example, a tunnel insulating film 44, a charge storage film 45, and a block insulating film 46.

The core film 41 is provided, for example, at the center of the memory pillar MP. The semiconductor film 42 surrounds the core film 41 laterally. The tunnel insulating film 44 surrounds the semiconductor film 42 laterally. The charge storage film 45 surrounds the tunnel insulating film 44 laterally. The block insulating film 46 surrounds the charge storage film 45 laterally. The interconnect layer 23 surrounds the block insulating film 46 laterally. The semiconductor film 42 is used as a channel (current path) for the memory cell transistors MT0 to MT7 and the select transistors ST1 and ST2. The tunnel insulating film 44 and the block insulating film 46 each include, for example, silicon dioxide. The charge storage film 45 includes, for example, silicon nitride.

Due to the above configuration, the memory pillars MP each function as one NAND string NS. That is, the portion at which each memory pillar MP and the interconnect layer 22 intersect functions as the select transistor ST2. The portion at which each memory pillar MP and each interconnect layer 23 intersect functions as a memory cell transistor MT. The portion at which each memory pillar MP and the interconnect layer 24 intersect functions as the select transistor ST1.

A contact CV is provided on the upper face in the Z1 direction of the semiconductor film 42 of each memory pillar MP. For example, the contact CV tapers such that its diameter decreases in the Z2 direction. A conductive layer 25a is provided on the upper face in the Z1 direction of the contact CV. For example, the conductive layer 25a is formed like a line and extends in the Y direction. The conductive layer 25a includes, for example, copper and is used as a bit line BL.

In the hookup region HR, the contacts CC each extend in the Z direction. For example, the contacts CC taper such that their diameters decrease in the Z2 direction. The contacts CC are each provided in contact with the terrace portion of the corresponding interconnect layer of the interconnect layers 22 to 24 but away from the other interconnect layers.

A conductive layer 25b is provided on the upper face in the Z1 direction of each contact CC. The conductive layer 25b includes, for example, copper and is provided in the same layer in which the conductive layer 25a is provided. Hereinafter, the layer in which the conductive layers 25a and 25b are provided is referred to as a layer M0.

The stacked interconnect structure, the contacts CC and CV, and the conductive layers 25a and 25b as above are covered with the insulating layer 35.

### 1.4 Row Decoder Module

Next, the configuration of the row decoder module according to the embodiment will be described.

### 1.4.1 Circuit Configuration

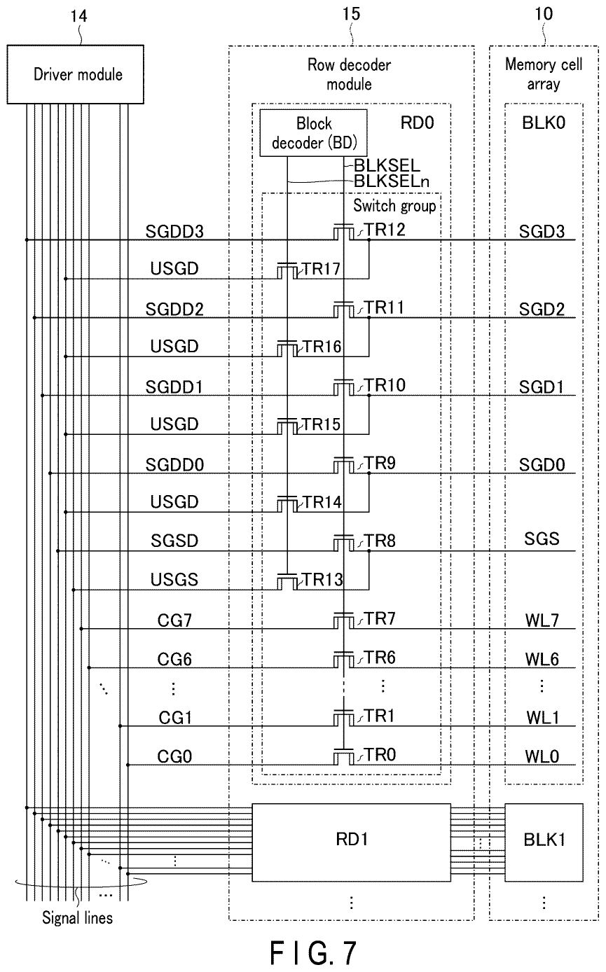

FIG. 7 is a circuit diagram illustrating an exemplary circuit configuration of the row decoder module included in the memory device according to the embodiment. As illustrated in FIG. 7, the row decoder module 15 includes a plurality of row decoders RD (RD0, RD1, . . . ). The number of row decoders RD corresponds to the number of blocks BLK. The row decoders RD are identical in configuration. In the example of FIG. 7, the configuration of the row decoder RD0 corresponding to the block BLK0 is illustrated. The row decoder RD0 includes a block decoder BD and a switch group WLSW. The switch group WLSW includes a plurality of transistors TR (TR0 to TR17).

For example, the transistors TR0 to TR12 are each an N-type transistor. The transistors TR0 to TR7 have their first ends connected to the block BLK0 through the word lines WL0 to WL7, respectively. The transistors TR0 to TR7 have their second ends connected to the driver module 14 through interconnects CG0 to CG7, respectively. The transistors TR0 to TR7 have their gates connected to the block decoder BD through an interconnect BLKSEL.

For example, in the write operation, the transistors TR0 to TR7 may transfer write voltages to the word lines WL0 to WL7, respectively. Such a write voltage is high enough to raise the threshold voltage of a memory cell transistor MT. Thus, the transistors TR0 to TR7 each have a high breakdown voltage to transfer the write voltage. Hereinafter, a transistor having a high breakdown voltage to transfer the write voltage is also referred to as a “high breakdown voltage transistor” or “HV transistor”. For the HV transistor, its gate oxide film has a thickness of at least 10 nm or more. For a transistor capable of operating up to 30 V, for example, its gate oxide film is designed to have a thickness of approximately 40 nm. In contrast to the HV transistor, a transistor having a low breakdown voltage is also referred to as a “low breakdown voltage transistor” or “LV transistor”. For the LV transistor, for example, its gate oxide film is designed to have a thickness of 5 nm to 7 nm. A transistor having a further lower breakdown voltage than that of the LV transistor is also referred to as a “very low breakdown voltage transistor” or “VLV transistor”. For the VLV transistor, for example, its gate oxide film is designed to have a thickness of 2.5 nm to 3.5 nm.

The transistor TR8 is, for example, an N-type HV transistor. The transistor TR8 has its first end connected to the block BLK0 through the select gate line SGS. The transistor TR8 has its second end connected to the driver module 14 through an interconnect SGSD. The transistor TR8 has its gate connected to the block decoder BD through the interconnect BLKSEL.

The transistors TR9 to TR12 are each, for example, an N-type HV transistor. The transistors TR9 to TR12 have their first ends connected to the block BLK0 through the select gate lines SGD0 to SGD3, respectively. The transistors TR9 to TR12 have their second ends connected to the driver module 14 through interconnects SGDD0 to SGDD3, respectively. The transistors TR9 to TR12 have their gates connected to the block decoder BD through the interconnect BLKSEL.

The transistor TR13 is, for example, an N-type HV transistor. The transistor TR13 has its first end connected to the block BLK0 through the select gate line SGS. The transistor TR13 has its second end connected to the driver module 14 through an interconnect USGS. The transistor TR13 has its gate connected to the block decoder BD through an interconnect BLKSELn.

The transistors TR14 to TR17 are each, for example, an N-type HV transistor. The transistors TR14 to TR17 have their first ends connected to the block BLK0 through the select gate lines SGD0 to SGD3, respectively. The transistors TR14 to TR17 have their second ends connected to the driver module 14 through an interconnect USGD. The transistors TR14 to TR17 have their gates connected to the block decoder BD through the interconnect BLKSELn.

The block decoder BD supplies voltages mutually different in logic level to the interconnects BLKSEL and BLKSELn. In a case where the block BLK0 is selected, the block decoder BD supplies the “H” level voltage to the interconnect BLKSEL and the “L” level voltage to the interconnect BLKSELn. In a case where no block BLK0 is selected, the block decoder BD supplies the “L” level voltage to the interconnect BLKSEL and the “H” level voltage to the interconnect BLKSELn.

### 1.4.2 Planar Layout

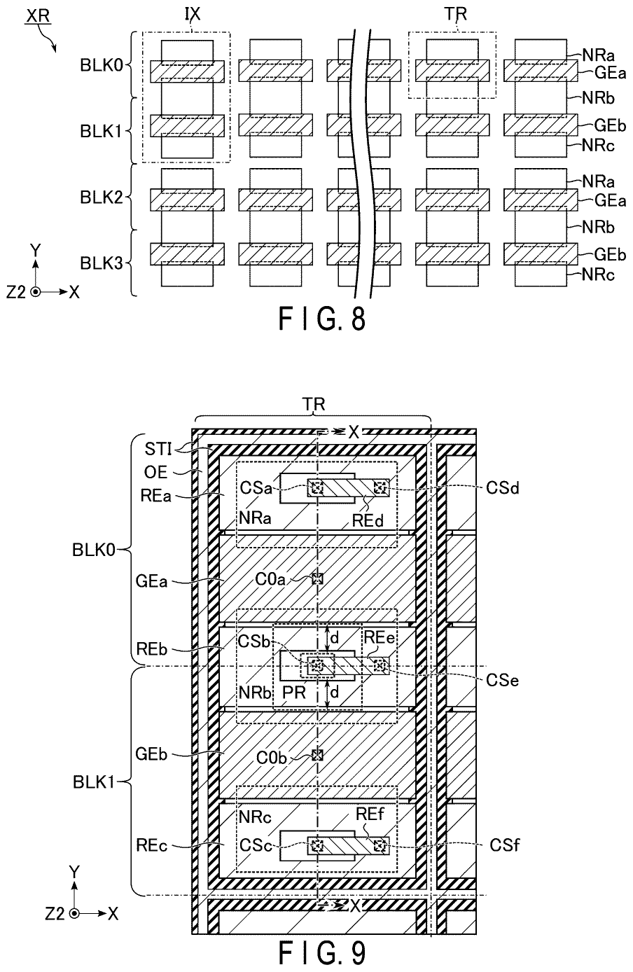

FIG. 8 is a plan view illustrating an exemplary planar layout of the row decoder module included in the memory device according to the embodiment. Referring to FIG. 8, illustrated is a planar layout of a plurality of transistors TR included in four switch groups WLSW corresponding to four blocks BLK0 to BLK3 in a region XR in which the row decoder module 15 is disposed.

As illustrated in FIG. 8, in the region XR, the transistors TR included in each of the switch groups WLSW are arranged in the X direction. Then, the switch groups WLSW are arranged in the Y direction. In the example of FIG. 8, the switch group WLSW corresponding to the block BLK3, the switch group WLSW corresponding to the block BLK2, the switch group WLSW corresponding to the block BLK1, and the switch group WLSW corresponding to the block BLK0 are arranged in this order in the Y direction.

Each transistor TR includes an impurity diffusion region NR that functions as its source, an impurity diffusion region NR that functions as its drain, and an electrode GE that functions as its gate. One of the two impurity diffusion regions NR included in one transistor TR, the electrode GE, and the other impurity diffusion region NR are arranged in this order in the Y direction.

As described above, the transistors TR arranged in the X direction in each switch group WLSW correspond to the same block BLK. Thus, the electrodes GE arranged in the X direction are electrically connected. In the example of FIG. 8, the electrodes GE arranged in the X direction are disposed away from each other, but this is not limiting. The electrodes GE arranged in the X direction may be disposed as one conductor extending in the X direction.

Two transistors TR arranged in the Y direction share one impurity diffusion region NR. In the example of FIG. 8, one of the transistors TR corresponding to the block BLK0 and one of the transistors TR corresponding to the block BLK1 share one impurity diffusion region NR. One of the transistors TR corresponding to the block BLK2 and one of the transistors TR corresponding to the block BLK3 share one impurity diffusion region NR.

Two transistors TR sharing one impurity diffusion region NR include three impurity diffusion regions NR and two electrodes GE. As the three impurity diffusion regions NR and two electrodes GE, an impurity diffusion region NRc, an electrode GEb, a common impurity diffusion region NRb, an electrode GEa, and an impurity diffusion region NRa are arranged in this order in the Y direction.

FIG. 9 is a plan view illustrating an example of a region IX of FIG. 8 in the planar layout of the row decoder module included in the memory device according to the embodiment. Referring to FIG. 9, two transistors TR sharing an impurity diffusion region NRb are illustrated. One of the two transistors TR corresponds to the block BLK0 and the other corresponds to the block BLK1.

As illustrated in FIG. 9, the two transistors TR include impurity diffusion regions NRa, NRb, NRc, and PR, electrodes GEa, GEb, REa, REb, REc, REd, REe, REf, and OE, contacts C0a, C0b, CSa, CSb, CSc, CSd, CSe, and CSf, and an element separation region STI.

The impurity diffusion regions NRa, NRb, and NRc are arranged away from each other in the Y direction. For example, the impurity diffusion regions NRa, NRb, and NRc are each rectangular in shape. The impurity diffusion region PR is disposed in the impurity diffusion region NRb. For example, the impurity diffusion region PR is shaped like a quadrangular ring. The impurity diffusion region NRb fills inside the quadrangular ring of the impurity diffusion region PR.

As viewed in the Z direction, the electrodes REa, REb, and REc overlap the impurity diffusion regions NRa, NRb, and NRc, respectively. That is, the electrodes REa, REb, and REc are arranged away from each other in the Y direction. The electrodes REa, REb, and REc are each shaped like a quadrangular ring. In other words, the electrodes REa, REb, and REc each have an opening.

The contact CSa extending in the Z2 direction is provided on the impurity diffusion region NRa. The contact CSa passes through the opening of the electrode REa without being in contact with the electrode REa. The contact CSd extending in the Z2 direction is provided on the electrode REa. Then, the electrode REd extending in the Y direction is provided such that the respective upper faces in the Z2 direction of the contacts CSa and CSd are connected together. Thus, the electrode REa is electrically connected to the impurity diffusion region NRa such that the electrode REa is substantially identical in potential to the impurity diffusion region NRa.

The contact CSb extending in the Z2 direction is provided on the portion surrounded by the impurity diffusion region PR in the impurity diffusion region NRb. The contact CSb passes through the opening of the electrode REb without being in contact with the electrode REb. The contact CSe extending in the Z2 direction is provided on the electrode REb. Then, the electrode REe extending in the Y direction is provided such that the respective upper faces in the Z2 direction of the contacts CSb and CSe are connected together. Thus, the electrode REe is electrically connected to the impurity diffusion region NRb such that the electrode REe is substantially identical in potential to the impurity diffusion region NRb.

The contact CSc extending in the Z2 direction is provided on the impurity diffusion region NRc. The contact CSc passes through the opening of the electrode REc without being in contact with the electrode REc. The contact CSf extending in the Z2 direction is provided on the electrode REc. Then, the electrode REf extending in the Y direction is provided such that the respective upper faces in the Z2 direction of the contacts CSc and CSf are connected together. Thus, the electrode REc is electrically connected to the impurity diffusion region NRc such that the electrode REc is substantially identical in potential to the impurity diffusion region NRc.

The electrode GEa is provided between the electrode REa and the electrode REb. As viewed in the Z direction, the electrode GEa includes an overlap with the impurity diffusion region NRa and an overlap with the impurity diffusion region NRb. The contact C0a extending in the Z2 direction is provided on the electrode GEa.

The electrode GEb is provided between the electrode REb and the electrode REc. As viewed in the Z direction, the electrode GEb includes an overlap with the impurity diffusion region NRc and an overlap with the impurity diffusion region NRb. The contact C0b extending in the Z2 direction is provided on the electrode GEb.

As viewed in the Z direction, the boundary between the impurity diffusion region PR and the impurity diffusion region NRb is located in the region between the electrode GEa and the electrode REb, for example. As viewed in the Z direction, the boundary between the impurity diffusion region PR and the impurity diffusion region NRb is located in the region between the electrode GEb and the electrode REb, for example. The length d in the Y direction of the portion between the contact CSb and the contact C0a of the impurity diffusion region PR is preferably longer, from the viewpoint of an improvement in the breakdown voltage of a transistor TR. Similarly, the length d in the Y direction of the portion between the contact CSb and the contact C0bof the impurity diffusion region PR is preferably longer, from the viewpoint of an improvement in the breakdown voltage of a transistor TR.

The element separation region STI surrounds the impurity diffusion regions NRa, NRb, and NRc, and the electrodes REa, REb, REc, GEa, and GEb. Thus, the two transistors TR are electrically insulated from the other transistors TR.

The electrode OE surrounds the impurity diffusion regions NRa, NRb, and NRc, and the electrodes REa, REb, REc, GEa, and GEb. As viewed in Z direction, the electrode OE overlaps the element separation region STI. The electrode OE is electrically insulated from the other electrodes and the impurity diffusion regions. For example, at the time of the write operation or the read operation, the electrode OE is brought into floating.

### 1.4.3 Sectional Structure

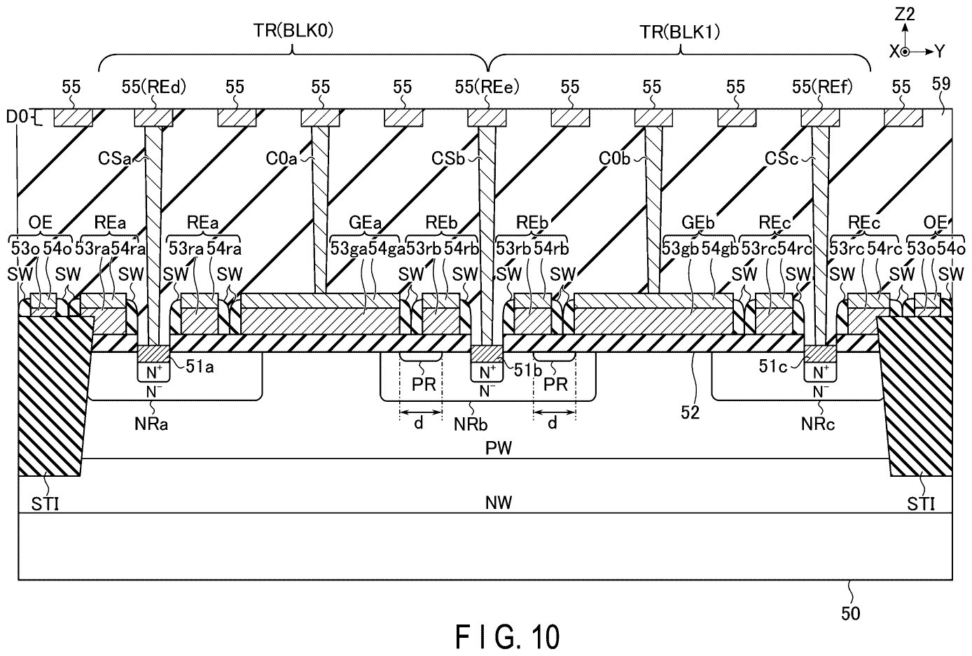

FIG. 10 is a sectional view taken along line X-X of FIG. 9, illustrating an exemplary sectional structure of the row decoder module included in the memory device according to the embodiment. Referring to FIG. 10, illustrated is a sectional structure of two transistors TR sharing an impurity diffusion region NRb in the region XR. Referring to FIG. 10, the Z2 direction corresponds to the up direction of the drawing.

As illustrated in FIG. 10, the transistors TR are provided on a substrate 50. The substrate 50 is, for example, a silicon substrate.

The substrate 50 has an upper portion in which a well region NW is formed. The well region NW includes N-type impurities, such as phosphorus (P) or arsenic (As). The upper face in the Z2 direction of the well region NW is flush with the upper face in the Z2 direction of the substrate 50.

The well region NW has an upper portion in which a well region PW is formed. The well region PW includes P-type conductive impurities, such as boron (B) or indium (In), different from the N-type impurities. As viewed in the Z direction, the well region PW is included in the well region NW. The upper face in the Z2 direction of the well region PW is flush with the upper face in the Z2 direction of the substrate 50.

The well region NW has its upper portion in which the element separation region STI is further formed and surrounds the well region PW. The element separation region STI is deeper than the well region PW but is shallower than the well region NW. The upper face in the Z2 direction of the element separation region STI is located higher in the Z2 direction than the upper face in the Z2 direction of the substrate 50.

The well region PW has an upper portion in which the impurity diffusion regions NRa, NRb, and NRc are formed away from each other in the Y direction. The impurity diffusion regions NRa, NRb, and NRc each include N-type impurities. As viewed in the Z direction, the impurity diffusion regions NRa, NRb, and NRc are included in the well region PW. The respective upper faces in the Z2 direction of the impurity diffusion regions NRa, NRb, and NRc are flush with the upper face in the Z2 direction of the substrate 50.

The impurity diffusion regions NRa, NRb, and NRc each include a region N⁻ and a region N⁺. The region N⁻ has a relatively low concentration of N-type impurities. The region N⁺ has a relatively high concentration of N-type impurities. The impurity diffusion regions NRa, NRb, and NRc each have the region N⁺ located at the center. As viewed in the Z direction, the region N⁻ surrounds the region N⁺.

The region N⁻ of the impurity diffusion region NRb has an upper portion in which the impurity diffusion region PR is formed. The impurity diffusion region PR includes P-type impurities. For example, the impurity concentration of the impurity diffusion region PR is not less than the impurity concentration of the region N⁻. The upper face in the Z2 direction of the impurity diffusion region PR is flush with the upper face in the Z2 direction of the substrate 50. As viewed in the Z direction, the impurity diffusion region PR is included in the region N⁻. Thus, the impurity diffusion region PR is not continuous with the well region PW.

A conductive layer 51a is provided on the upper face in the Z2 direction of the region N⁺ of the impurity diffusion region NRa. A conductive layer 51b is provided on the upper face in the Z2 direction of the region N⁺ of the impurity diffusion region NRb. A conductive layer 51c is provided on the upper face in the Z2 direction of the region N⁺ of the impurity diffusion region NRc. For example, the conductive layers 51a, 51b, and 51c each include at least one compound selected from nickel silicide (NiSi), nickel platinum silicide (NiPtSi), and cobalt silicide (CoSi).

An insulating layer 52 is provided on the portion excluding the conductive layers 51a, 51b, and 51c on the upper face in the Z2 direction of the substrate 50 (namely, on the upper faces in the Z2 direction of the well regions NW and PW and the regions N⁻). The insulating layer 52 functions as a gate insulating film for a transistor TR.

Conductive layers 53 and 54 are stacked in this order on the upper faces in the Z2 direction of the insulating layer 52 and the element separation region STI. The conductive layer 53 includes, for example, polysilicon. The conductive layer 54 includes, for example, at least one compound selected from nickel silicide (NiSi), nickel platinum silicide (NiPtSi), and cobalt silicide (CoSi).

The conductive layer 53 includes portions 53ga, 53gb, 53ra, 53rb, 53rc, and 53o provided away from each other. The conductive layer 54 includes portions 54ga, 54gb, 54ra, 54rb, 54rc, and 54o stacked, respectively, on the portions 53ga, 53gb, 53ra, 53rb, 53rc, and 53o of the conductive layer 53. The portions 53ga and 54ga function as the electrode GEa. The portions 53gb and 54gb function as the electrode GEb. The portions 53ra and 54ra function as the electrode REa. The portions 53rb and 54rb function as the electrode REb. The portions 53rc and 54rc function as the electrode REc. The portions 53o and 54o function as the electrode OE.

Each of the portions that function as the electrodes GEa, GEb, REa, REb, REc, and OE in the conductive layers 53 and 54 has a side face provided with an insulating film SW.

The contact CSa is provided on the upper face in the Z2 direction of the conductive layer 51a. The contact CSb is provided on the upper face in the Z2 direction of the conductive layer 51b. The contact CSc is provided on the upper face in the Z2 direction of the conductive layer 51c.

The contact C0a is provided on the upper face in the Z2 direction of the portion 54ga of the conductive layer 54. The contact C0b is provided on the upper face in the Z2 direction of the portion 54gb of the conductive layer 54.

A conductive layer 55 is provided on the upper face in the Z2 direction of each of the contacts C0a, C0b, CSa, CSb, and CSc. A layer in which the conductive layer 55 is provided is referred to as a layer D0. In addition to the above-described conductive layer 55, a plurality of conductive layers 55 may be provided in the layer D0.

The transistors TR having the above configuration are covered with an insulating layer 59.

As described above, for example, the impurity diffusion region PR has the length d in the Y direction. The end on the side of location of the impurity diffusion region NRa of the portion between the region N⁺ of the impurity diffusion region NRb and the impurity diffusion region NRa, in the impurity diffusion region PR, is located, for example, as viewed in the Z direction, in the region of the insulating film SW provided between the electrodes GEa and REb. The end on the side of location of the impurity diffusion region NRc of the portion between the region N⁺ of the impurity diffusion region NRb and the impurity diffusion region NRc, in the impurity diffusion region PR, is located, for example, as viewed in the Z direction, in the region of the insulating film SW provided between the electrodes GEb and REb. From the viewpoint of an improvement in the breakdown voltage of a transistor TR, the width d is preferably longer toward the side of location of the region N⁺ without reaching the region N⁺ and the conductive layer 51b.

### 1.5 Entire Structure

Next, the entire structure of the memory device according to the embodiment will be described.

### 1.5.1 Bonding Structure

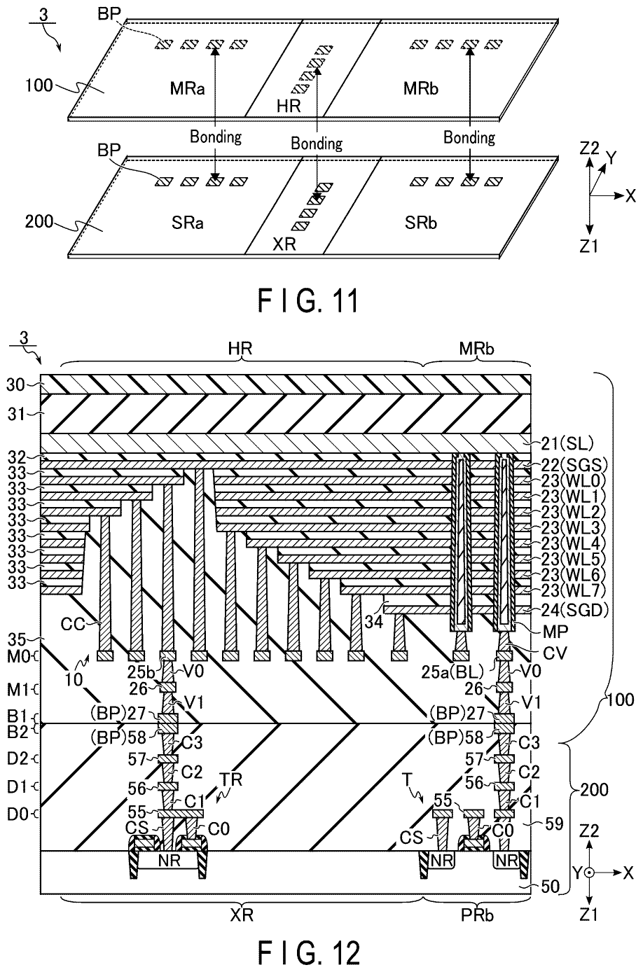

FIG. 11 is a schematic perspective view illustrating a bonding structure for the memory device according to the embodiment. As illustrated in FIG. 11, the memory device 3 includes a memory chip 100 and a circuit chip 200.

The memory chip 100 and the circuit chip 200 each include a plurality of bonding pads BP. The memory chip 100 and the circuit chip 200 are bonded together through the bonding pads BP to form the memory device 3.

The memory chip 100 has a structure corresponding to the memory cell array 10. The circuit chip 200 has a structure corresponding to, for example, the command register 11, the address register 12, the sequencer 13, the driver module 14, the row decoder module 15, and the sense amplifier module 16.

As described above, the memory chip 100 includes the memory regions MRa and MRb and the hookup region HR. The circuit chip 200 further includes regions SRa and SRb, in addition to the region XR. The region XR corresponds to a region to which the row decoder module 15 is provided. The regions SRa and SRb correspond to regions to which the command register 11, the address register 12, the sequencer 13, the driver module 14, and the sense amplifier module 16 are provided. The memory chip 100 and the circuit chip 200 are bonded together such that the memory region MRa, the hookup region HR, and the memory region MRb face the regions SRa, XR, and SRb, respectively.

### 1.5.2 Sectional Structure

FIG. 12 is a sectional view illustrating an exemplary sectional structure of the memory device according to the embodiment. Referring to FIG. 12, the Z2 direction corresponds to the up direction of the drawing.

As illustrated in FIG. 12, the memory device 3 further includes conductive layers 26 and 27, a protective layer 30, and contacts V0 and V1 in the memory chip 100. The memory device 3 further includes conductive layers 56, 57, and 58, contacts C1, C2, and C3, and a transistor T in the circuit chip 200.

First, the memory chip 100 will be described.

The protective layer 30 is provided on the upper face in the Z2 direction of the insulating layer 31. The protective layer 30 corresponds to the surface of the memory device 3 and includes a resin material, such as polyimide. In a region not illustrated, portion of the protective layer 30 is removed. Then, the portion from which the protective layer 30 is removed is provided with a power supply pad for external electrical connection.

The contact V0 is provided on the upper surface in the Z1 direction of each of the conductive layers 25a and 25b. For example, the contact V0 tapers such that its diameter decreases in the Z2 direction. The conductive layer 26 is provided on the upper surface in the Z1 direction of the contact V0.

The contact V1 is provided on the upper face in the Z1 direction of the conductive layer 26. For example, the contact V1 tapers such that its diameter decreases in the Z2 direction. The conductive layer 27 is provided on the upper face in the Z1 direction of the contact V1. The conductive layer 27 functions as a bonding pad BP on the bonding face between the memory chip 100 and the circuit chip 200. The conductive layers 26 and 27 and the contacts V0 and V1 are covered with the insulating layer 35. The layers in which the conductive layers 26 and 27 are provided are referred to as a layer M1 and a bonding layer B1, respectively.

Next, the circuit chip 200 will be described.

The regions XR and SR on the substrate 50 are provided with transistors TR and T, respectively. For example, the transistor T is included in the sense amplifier module 16. The transistor T may be identical in configuration to the transistor TR. The transistor TR has its drain, gate, and source arranged in the Y direction, whereas the transistor T has its drain, gate, and source arranged in the X direction.

A contact C0 is provided on the upper face in the Z2 direction of the gate insulating film of each of the transistors TR and T. A contact CS is provided on the upper face in the Z2 direction of the source or drain of each of the transistors TR and T. The conductive layer 55 is provided on the upper face in the Z2 direction of each of the contacts CS and C0.

The contact C1 is provided on the upper face in the Z2 direction of the conductive layer 55. The conductive layer 56 is provided on the upper face in the Z2 direction of the contact C1. The contact C2 is provided on the upper face in the Z2 direction of the conductive layer 56. The conductive layer 57 is provided on the upper face in the Z2 direction of the contact C2. The contact C3 is provided on the upper face in the Z2 direction of the conductive layer 57. The conductive layer 58 is provided on the upper face in the Z2 direction of the contact C3. In contact with the corresponding conductive layer 27, the conductive layer 58 functions as a bonding pad BP on the bonding face with the memory chip 100. The conductive layers 55, 56, 57, and 58, and the contacts CS, C0, C1, C2, and C3 are covered with the insulating layer 59. The layers in which the conductive layers 56, 57, and 58 are provided are referred to as a layer D1, a layer D2, and a bonding layer B2, respectively.

Due to the above configuration, the transistor TR is electrically connected to the gate of a memory cell transistor MT through a word line WL. The transistor T is electrically connected to the end on the side of location of the select transistor ST1 of a NAND string NS through a bit line BL.

### 2. Effect

At the time of the write operation or the read operation, high voltage is applied to transistors TR. Thus, such transistors TR are required to have a high breakdown voltage. According to the embodiment, an improvement can be made in the breakdown voltage of a transistor TR. The present effect will be described below.

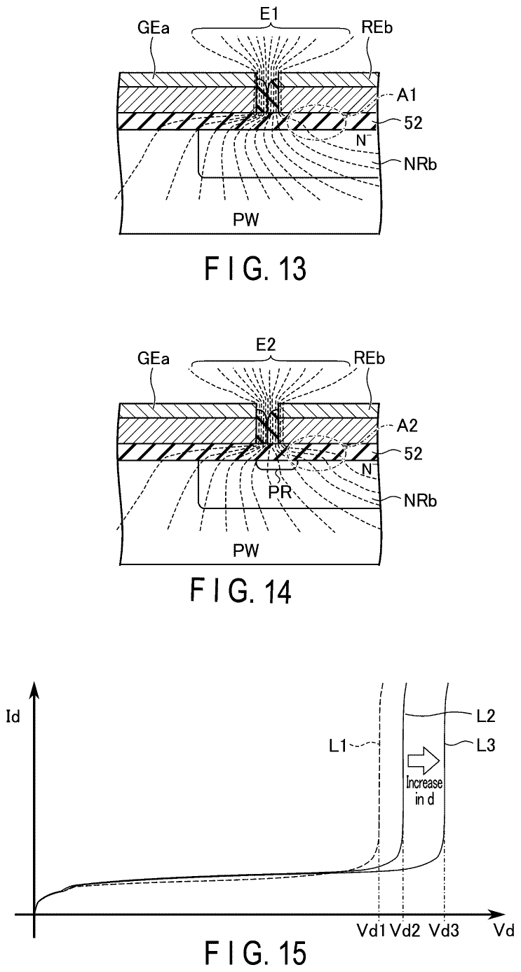

FIG. 13 illustrates an exemplary potential distribution on a transistor included in a memory device according to a comparative example. FIG. 14 illustrates an exemplary potential distribution on a transistor included in the memory device according to the embodiment. The comparative example corresponds to a case where no impurity diffusion region PR is formed in an impurity diffusion region NRb. Referring to FIG. 13, a potential distribution E1 on the impurity diffusion region NRb at the time of application of high voltage is indicated with dashed lines. Referring to FIG. 14, a potential distribution E2 on the impurity diffusion region NRb at the time of application of high voltage is indicated with dashed lines.

As illustrated in a region A1 of FIG. 13, with no impurity diffusion region PR formed, the potential distribution E1 is low in density on the side of location of the electrode REb at the boundary between the region Nand the insulating layer 52 and thus is biased on the side of location of the electrode GEa. Thus, the electric field concentrates on the side of location of the electrode GEa in the region N⁻, resulting in a situation where a breakdown is likely to be easily made.

In contrast to this, as illustrated in a region A2 of FIG. 14, with the impurity diffusion region PR formed, the potential distribution E2 ranges not only on the side of location of the electrode GEa but also on the side of location of the electrode REb at the boundary between the region N⁻ and the insulating layer 52. Thus, a breakdown is inhibited from being made with relaxation of electric-field concentration on the side of location of the electrode GEa.

FIG. 15 illustrates an exemplary characteristic of a transistor included in the memory device according to the embodiment. Referring to FIG. 15, the vertical axis corresponds to current Id flowing to the drain of a transistor TR and the horizontal axis corresponds to voltage Vd applied to the drain of the transistor TR. Then, the current-voltage characteristic of a transistor TR in the comparative example is indicated with a dot-and-dash line L1. The current-voltage characteristics of transistors TR according to the embodiment are indicated with solid lines L2 and L3. The width d varies between the solid lines L2 and L3. That is, the width d corresponding to the solid line L3 is larger than the width d corresponding to the solid line L2.

As illustrated in FIG. 15, with no impurity diffusion region PR formed, a breakdown is made at a voltage Vd1. With the impurity diffusion region PR formed, a breakdown is inhibited from being made to a voltage Vd2 higher than the voltage Vd1. Then, due to an increase in the width d of the impurity diffusion region PR, a breakdown is further inhibited from being made to a voltage Vd3 higher than the voltage Vd2.

As above, according to the embodiment, due to the formation of the impurity diffusion region PR in the region N⁻, an improvement can be made in the breakdown voltage of a transistor TR.

### 3. Modifications

Various modifications can be applied to the above-described embodiment.

### 3.1 First Modification

In the above-described embodiment, a case where the contact CSa passes through the opening of the electrode REa and the contact CSc passes through the opening of the electrode REc has been given, but this is not limiting. For example, as a configuration, the contact CSa may pass through the opening of the electrode GEa and the contact CSc may pass through the opening of the electrode GEb.

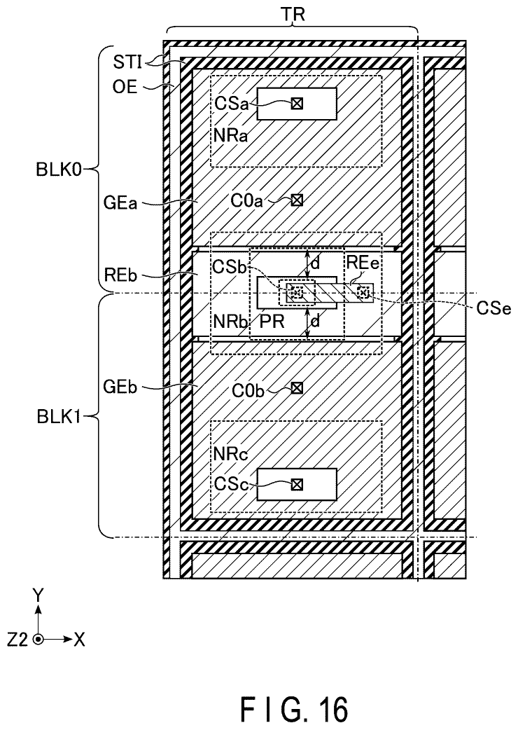

FIG. 16 is a plan view illustrating an exemplary planar layout of a row decoder module included in a memory device according to a first modification. FIG. 16 corresponds to FIG. 9 in the embodiment.

As illustrated in FIG. 16, no electrodes REa and REc may be provided. In this case, an electrode GEa is provided such that an impurity diffusion region NRa is covered with the electrode GEa as viewed in the Z direction, and has an opening. A contact CSa passes through the opening of the electrode GEa and extends in the Z direction. An electrode GEb is provided such that an impurity diffusion region NRc is covered with the electrode GEb as viewed in the Z direction, and has an opening. A contact CSc passes through the opening of the electrode GEb and extends in the Z direction.

Even with the above configuration, an impurity diffusion region PR is provided in an impurity diffusion region NRb, leading to relaxation of electric-field concentration in a region N⁻. Thus, an improvement can be made in the breakdown voltage of a transistor TR.

### 3.2 Second Modification

In the above-described embodiment and first modification, a case where the contact CSb passes through the opening of the electrode REb has been given, but this is not limiting. For example, as a configuration, no electrode REb may be provided and the contact CSb may pass between the electrode GEa and GEb.

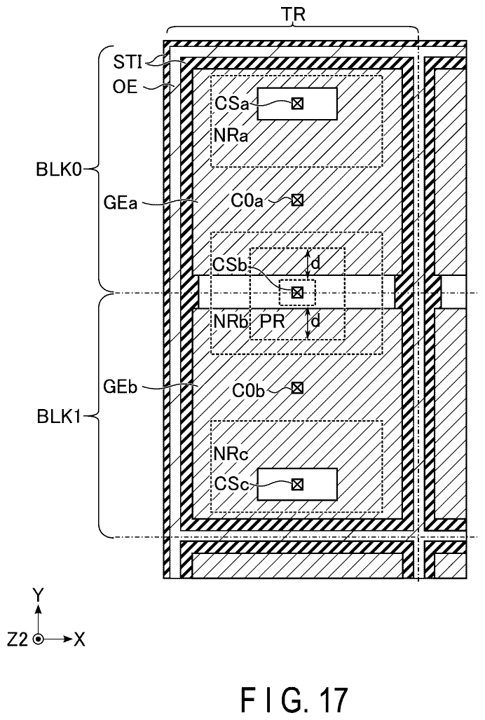

FIG. 17 is a plan view illustrating an exemplary planar layout of a row decoder module included in a memory device according to a second modification. FIG. 17 corresponds to FIG. 16 in the first modification.

As illustrated in FIG. 17, no electrode REb may be provided. In this case, an electrode GEa is provided such that the side of location of a contact CSa of an impurity diffusion region NRb with respect to a contact CSb is covered with the electrode GEa as viewed in the Z direction. An electrode GEb is provided such that the side of location of a contact CSc of the impurity diffusion region NRb with respect to the contact CSb is covered with the electrode GEb as viewed in the Z direction. The contact CSb passes between the electrodes GEa and GEb and extends in the Z direction.

Even with the above configuration, an impurity diffusion region PR is provided in the impurity diffusion region NRb, leading to relaxation of electric-field concentration in a region N−. Thus, an improvement can be made in the breakdown voltage of a transistor TR.

### 3.3 Others

In the above-described embodiment, first modification, and second modification, a case where the impurity diffusion region PR is annually provided in the region N− of the impurity diffusion region NRb such that the region N+ of the impurity diffusion region NRb is surrounded by the impurity diffusion region PR has been given, but this is not limiting. For example, provided that the impurity diffusion region PR includes a portion extending in the X direction between the region N+ of the impurity diffusion region NRb and the region N+ of the impurity diffusion region NRa and a portion extending in the X direction between the region N+ of the impurity diffusion region NRb and the region N+ of the impurity diffusion region NRc, the impurity diffusion region PR may include no portion extending in the Y direction. Even with the above configuration, an improvement can be made in the breakdown voltage of a transistor TR.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a first region, a third region, and a second region provided in a substrate, arranged away from each other in a first direction in this order, and each including a first conductive impurity;
a fourth region provided in the third region, and including a second conductive impurity different from the first conductive impurity;
a first conductive layer provided above the first region, and including a first opening;
a second conductive layer provided above the second region, and including a second opening;
a first contact connected to the first region, and passing through the first opening;
a second contact connected to the second region, and passing through the second opening;
a first memory cell connected to the first contact; and
a second memory cell connected to the second contact.

2. The memory device according to claim 1, wherein
a concentration of the second conductive impurity included in the fourth region is equal to or more than a concentration of the first conductive impurity included in the third region.

3. The memory device according to claim 1, further comprising:
a first well region provided in the substrate, and including the first conductive impurity; and
a second well region provided in the first well region, and including the second conductive impurity, wherein
the first region, the second region, and the third region are provided in the second well region.

4. The memory device according to claim 3, wherein
the third region includes a portion between the fourth region and the second well region.

5. The memory device according to claim 3, further comprising:
an insulating film provided in the first well region, wherein
the insulating film surrounds the second well region.

6. The memory device according to claim 1, further comprising:
a third contact connected to the third region, and passing between the first conductive layer and the second conductive layer.

7. The memory device according to claim 6, wherein
as viewed from above, the fourth region includes: a portion extending in the first direction between the first conductive layer and the third contact; and a portion extending in the first direction between the second conductive layer and the third contact.

8. The memory device according to claim 6, wherein
as viewed from above, the fourth region surrounds the third contact.

9. The memory device according to claim 6, further comprising:
a third conductive layer provided above the third region, and including a third opening, wherein the third contact passes through the third opening.

10. The memory device according to claim 9, wherein
the third conductive layer is electrically connected to the third region.

11. The memory device according to claim 9, wherein
as viewed from above, a boundary between the third region and the fourth region is located between the third conductive layer and the first conductive layer and between the third conductive layer and the second conductive layer.

12. The memory device according to claim 9, further comprising:
a fourth conductive layer provided between the first conductive layer and the third conductive layer in the first direction; and
a fifth conductive layer provided between the second conductive layer and the third conductive layer in the first direction.

13. The memory device according to claim 12, wherein
the fourth conductive layer is electrically connected to the first region, and
the fifth conductive layer is electrically connected to the second region.

14. The memory device according to claim 12, wherein
as viewed from above, a boundary between the third region and the fourth region is located between the third conductive layer and the fourth conductive layer and between the third conductive layer and the fifth conductive layer.

15. The memory device according to claim 1, further comprising:
a first transistor including: a first end electrically connected to the first region; and a second end electrically connected to the third region; and
a second transistor including: a first end electrically connected to the second region; and a second end electrically connected to the third region.

16. The memory device according to claim 1, further comprising:
a first block including a plurality of memory cells including the first memory cell; and
a second block including a plurality of memory cells including the second memory cell, wherein each of the first block and the second block is a unit of data erasure.

17. The memory device according to claim 16, further comprising:
a plurality of transistors connected to the respective memory cells in the first block, wherein
the transistors are arranged in a second direction intersecting with the first direction.
